(19) United States
(12) Patent Application Publication
(10) Pub. No.: US 2024/0352279 A1
(43) Pub. Date: Oct. 24, 2024

(54) PAD-IN-A-BOTTLE (PIB) TECHNOLOGY FOR COPPER BARRIER SLURRIES

(71) Applicant: Versum Materials US, LLC, Tempe, AZ (US)

(72) Inventors: Xiaobo Shi, Chandler, AZ (US); Mark Leonard O'Neill, Queen Creek, AZ (US); John G. Langan, Tempe, AZ (US); Robert Vacassy, Phoenix, AZ (US); Jame Allen Schlueter, Phoenix, AZ (US); Yasa Sampurno, Tucson, AZ (US); Ara Philipossian, Tucson, AZ (US)

(21) Appl. No.: 18/291,036

(22) PCT Filed: Jul. 15, 2022
(86) PCT No.: PCT/US22/73794

§ 371 Date: Jan. 22, 2024

Related U.S. Application Data
(60) Provisional application No. 63/224,956, filed on Jul. 23, 2021.

(51) Int. Cl. C09G 1/02; H01L 21/3105; H01L 21/321

(52) U.S. Cl. CPC C09G 1/02; H01L 21/31053; H01L 21/3212

(57) ABSTRACT

A novel pad-in-a-bottle (PIB) technology for advanced chemical-mechanical planarization (CMP) copper barrier CMP compositions, systems and processes has been disclosed for use with polyurethane-based polishing pads having a plurality of asperities. The CMP composition comprises abrasives, polyurethane beads, and surfactant. The polishing pad lifetime increasing is achieved using PIB-type Cu barrier CMP polishing composition.

### CROSS-REFERENCE OF RELATED APPLICATIONS

This application claims the benefit of priority to U.S. provisional application Ser. No. 63/224,956, filed Jul. 23, 2021, which is incorporated herein by reference in its entirety.

### BACKGROUND OF THE INVENTION

This disclosure relates generally to a novel pad-in-a-bottle (PIB) technology for advanced chemical-mechanical planarization (CMP) compositions, systems, and processes. Specifically, the present disclosure relates to PIB technology for advanced Copper Barrier CMP compositions, systems, and processes.

In CMP, asperities on a polyurethane (PU) pad are irreversibly deformed due to wafer contact and are also abraded by composition particles. As such, the pad surface must be continuously renewed with a diamond disk to ensure process stability. Because the diamond disk has to cut the pad surface to eliminate old asperities and create new ones, pad renewal also gradually thins the pad, forcing its replacement.

Thus, conventional CMP has several weaknesses, such as (a) large amounts of waste is created (due to frequent replacement of pads and conditioners), and (b) poorly controlled shapes of pad asperities that cause highly-variable contact area distributions. These result in variations in removal rate (RR) and negatively affect wafer-level topography, among other things.

Thus, there are needs in the art of CMP to overcome the weakness of the conventional technology, such as improving polishing pad lifetime and conditioning disk life.

### BRIEF SUMMARY

The needs are satisfied with the presently disclosed novel pad-in-a-bottle (PIB) technology. The pad-in-a-bottle (PIB) technology for advanced node copper barrier CMP compositions, systems and processes has been developed to meet challenging requirements to improve polishing pad lifetime and conditioning disk life through the adoption and use of the PIB type of Cu barrier CMP slurries, which contain normal Cu barrier slurry compositions plus selected polyurethane beads and dispersing agent and using fractional conditioning conditions. The present application discloses new novel pad-in-a-bottle (PIB) technology that can improve pad life in Cu barrier CMP Processes.

The results show that about 4× longer soft pad life is achieved with PIB type of Cu barrier slurry using fractional conditioning process as compared to the pad life obtained using Non-PIB Cu barrier slurry with dispersing agent, but not contain polyurethane beads at full conditioning condition.

The results show that about 2× longer soft pad life is achieved with PIB type of Cu barrier slurry using fractional conditioning process than the pad life obtained using Non-PIB Cu barrier slurry with dispersing agent, not containing polyurethane beads at the same fractional conditioning condition.

In one aspect, PIB type of CMP polishing compositions is provided. The PIB type of CMP polishing composition comprises:
abrasives,
micron-size polyurethane (PU) beads ranging from 2 to 100 μm, 10 to 80 μm, 20 to 70 μm, or 30 to 50 μm;
a silicone-containing dispersing agent;
a corrosion inhibitor,
a liquid carrier such as water;
and optionally,
a surfactant to enhance film surface wetting;
an additive to boost dielectric film removal rates
a chelating agent,
a biocide;
pH adjuster;
an oxidizer added at the point of use; and
the pH of the composition is from 8.0 to 12.0; 8.5 to 11.0; or 9.0 to 10.0.

In another aspect, a CMP polishing method is provided. The CMP polishing method comprises:
providing the semiconductor substrate having a surface containing at least one material selected from the group consisting of Cu, TEOS, low-k (LK) or ultra low-k (Ultra-LK), TiN, Ti, Ta, and TaN;
providing a polishing pad;
providing the chemical mechanical polishing (CMP) Cu Barrier composition stated above;
contacting the surface containing at least one material selected from the group consisting of Cu, TEOS, low-k (LK) or ultra low-k (Ultra-LK), TiN, Ti, Ta, and TaN with the polishing pad and the chemical mechanical polishing formulation; and
polishing the surface containing at least one material selected from the group consisting of Cu, TEOS, low-k (LK) or ultra low-k (Ultra-LK), TiN, Ti, Ta, and TaN;
wherein at least a portion of the surface containing at least one of material selected from the group consisting of Cu, TEOS, low-k (LK) or ultra low-k (Ultra-LK), TiN, Ti, Ta, and TaN is in contact with both polishing pad and the chemical mechanical polishing formulation.

In yet another aspect, CMP polishing system is provided. The CMP polishing system comprises:
a semiconductor substrate having a surface containing at least one material selected from the group consisting of Cu, TEOS, low-k (LK) or ultra low-k (Ultra-LK), TiN, Ti, Ta, and TaN;
providing a polishing pad;
providing the chemical mechanical polishing (CMP) composition in claim stated above;
wherein at least a portion of the surface containing at least one material selected from the group consisting of Cu, TEOS, low-k (LK) or ultra low-k (Ultra-LK), TiN, Ti, Ta, and TaN is in contact with both the polishing pad and the chemical mechanical polishing formulation.

The abrasive particles include, but are not limited to, colloidal silica or high purity colloidal silica; the colloidal silica particles doped by other inorganic oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic oxide particles, such as alumina, titania, zirconia, ceria, etc.; nano-sized diamond particles, nano-sized silicon nitride particles; mono-modal, bi-modal, multi-modal colloidal abrasive particles; organic polymer-based soft abrasives, surface-coated or modified abrasives, or other composite particles, and mixtures thereof.

The silicone-containing dispersing agent includes, but is not limited to, silicone polyethers containing both a water-insoluble silicone backbone and a number of water-soluble polyether pendant groups to provide surface wetting properties. Examples are silicone polyethers containing both a water-insoluble silicone backbone and pendant groups comprising n repeating unit of ethylene oxide (EO) and propylene oxide (PO) (EO-PO) functional groups wherein n is 2 to 25.

The corrosion inhibitors include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The chelating agents (or chelators) include, but are not limited to, amino acids, amino acid derivatives, and organic amines.

The amino acids and amino acid derivatives include, but not limited to, glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof.

The surfactants included but not limited to, anionic surfactants, non-ionic and cationic surfactants.

The anionic surfactants include but are not limited to organic alkyl sulfonic acids with straight or branched alkyl chains, or their ammonium, sodium, or potassium salts of organic alkyl sulfonate surface wetting agents. Examples are dodecyl sulfonic acid, ammonium salt of dodecyl sulfonate, potassium salt of dodecyl sulfonate, sodium salt, dodecyl sulfonate, 7-Ethyl-2-methyl-4-undecyl sulfate sodium salt (such as Niaproof® 4), or sodium 2-ethylhexyl sulfate (such as Niaproof® 08).

The cationic surfactants include but are not limited to benzyldimethylhexadecylammonium chloride, dodecyltrimethylammonium chloride, dodecyltrimethylammonium hydroxide, cetyltrimethylammonium chloride, and cetyltrimethylammonium hydroxide.

The non-ionic surfactants are the surfactants containing ethylene oxide (EO) and propylene oxide (PO) functional groups include but are not limited to Dynol604, Dynol607, Surfynol 104, Tergitol Min-Form 1X, Tergitol L-62, and Tergitol L-64.

The dielectric film removal rate enhancing agents, included but not limited to, potassium silicate, sodium silicate, or ammonium silicate.

The biocide includes but is not limited to Kathon™, Kathon™ CG/ICP II, from Dow Chemical Co. They have active ingredients of 5-chloro-2-methyl-4-isothiazolin-3-one or/and 2-methyl-4-isothiazolin-3-one.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof.

The pH adjusting agents include, but are not limited to, the following: nitric acid, hydrochloric acid, sulfuric acid, phosphoric acid, other inorganic or organic acids, and mixtures thereof to adjust pH towards acidic direction. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

### DETAILED DESCRIPTION

The current application discloses a new technology where the role of pad asperities is played by high-quality micron-sized polyurethane (PU) beads ranging from 2 to 100 μm, 10 to 80 μm, 20 to 70 μm, or 30 to 50 μm; that are comparable to the sizes of pores and asperities in commercial polishing pads made from polyurethane.

The beads are suspended in a Cu Barrier CMP polishing composition having abrasive particles, such as a colloidal silica, high purity colloidal silica, or composite particles or other types of inorganic oxide particles with the assistance of a wetting agent (or a surfactant) as the dispersing agent to disperse polyurethane beads in aqueous compositions.

The beads come into contact with the wafer surface by a means described below to promote polishing loading in much the same way as conventional asperities.

By selecting both the size of the beads, and their concentration in the composition, much better control of the height, curvature, and area density of the “summits” that come in contact with the wafer is achieved. Control of the summits that come into contact with the wafer substantially reduces the process variability associated with conventional asperity contact.

Use of beads still requires a second surface, or counter-face, for polishing to occur, which in our case continues to be a conventional polyurethane-based pad, but one that requires minimal or fractional conditioning as it is no longer the primary surface where polishing takes place. Alternatively, one can use an inexpensive, solid, or partially conditioned pad as the counter-face.

A polisher may use 2 to 3 pads and conditioners simultaneously. End-of-life for a pad and a conditioning disk is typically reached after only 2 days of continuous use. Each platen in a CMP tool, therefore, uses hundreds of pads and conditioners annually, and since wafer fabrication facilities can have dozens of tools (with 2 or 3 platens on each tool), the total cost for pads and pad conditioners alone is substantial. The waste generated from the used polishing pad and conditioning disk is also substantial.

Since it can take several hours to remove a used pad, install, and qualify a new one, the engineering and product loss due to tool downtime and consumables used to qualify the new pad are also significant. Used PU pads and discarded diamond disk conditioners represent waste from the CMP processes which causes some environmental health and safety (EHS) issues.

As for a polishing pad, only about two-thirds of a pad thickness is used before the pad has to be stripped and discarded. For conditioner, only a few hundred diamonds out of tens of thousands control the product lifetime, after which the conditioner must be discarded. Furthermore, recycle or reuse options are not available for pads and conditioners. The present disclosure addresses the above EHS issues and offers a novel solution to the current standard CMP processes by reducing the use of lots of pads and diamond disk conditioners by increasing polishing pad and diamond conditioning disk lifetime through the combination of using PIB-type Cu Barrier slurry that contains the suitable micron sized polyurethane beads and dispersing agent under the fractional conditioning.

Several specific aspects of the present disclosure are outlined below.
Aspect 1. A PIB type of Cu Barrier CMP polishing composition comprises:
abrasives,
micron-size polyurethane (PU) beads ranging from 2 to 100 μm, 10 to 80 μm, 20 to 70 μm, or 30 to 50 μm;
a silicone-containing dispersing agent;
a corrosion inhibitor,
liquid carrier such as water;
and optionally,
a surfactant to enhance film surface wetting;
an additive to boost dielectric film removal rates
a chelating agent,
a biocide;
pH adjuster;
an oxidizer added at the point of use; and
the pH of the composition is from 8.0 to 12.0; 8.5 to 11.0; or 9.0 to 10.0.
Aspect 2: A CMP polishing method comprising:
providing the semiconductor substrate having a surface containing at least one of Cu, TEOS, low-k (LK) or ultra low-k (Ultra-LK), TiN, Ti, Ta, TaN film;
providing a polishing pad;
providing the chemical mechanical polishing (CMP) PIB (with PU Beads) or Non-PIB (without PU Beads) Cu Barrier formulation stated above;
contacting the surface containing at least one material selected from the group consisting of Cu, TEOS, low-k (LK) or ultra low-k (Ultra-LK), TiN, Ti, Ta, and TaN;
with the polishing pad and the chemical mechanical polishing formulation; and
polishing the surface containing at least one material selected from the group consisting of Cu, TEOS, low-k (LK) or ultra low-k (Ultra-LK), TiN, Ti, Ta, and TaN;
wherein at least a portion of the surface containing at least one material selected from the group consisting of Cu, TEOS, low-k (LK) or ultra low-k (Ultra-LK), TiN, Ti, Ta, and TaN is in contact with both polishing pad and the chemical mechanical polishing formulation.
Aspect 3: A CMP polishing system comprises:
a semiconductor substrate having a surface containing at least one material selected from the group consisting of Cu, TEOS, low-k (LK) or ultra low-k (Ultra-LK), TiN, Ti, Ta, and TaN;
providing a polishing pad;
providing the chemical mechanical polishing (CMP) formulation in claim stated above;
wherein at least a portion of the surface containing at least one material selected from the group consisting of Cu, TEOS, low-k (LK) or ultra low-k (Ultra-LK), TiN, Ti, Ta, and TaN is in contact with both the polishing pad and the chemical mechanical polishing formulation.

The abrasive particles are nano-sized particles, include, but are not limited to, colloidal silica or high purity colloidal silica; the colloidal silica particles doped by other inorganic oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasives, surface-coated or modified abrasives, or other composite particles, and mixtures thereof.

The colloidal silica can be made from silicate salts, the high purity colloidal silica can be made from TEOS or TMOS. The colloidal silica or high purity colloidal silica can have narrow or broad particle size distributions with mono-model or multi-models, various sizes and various shapes including spherical shape, cocoon shape, aggregate shape and other shapes,

The nano-sized particles also can have different shapes, such as spherical, cocoon, aggregate, and others.

The particle size of the abrasives used in the Cu Barrier CMP slurries ranges from 5 nm to 500 nm, 10 nm to 250 nm, or 25 nm to 100 nm.

The Cu Barrier CMP polishing compositions comprise 0.10 wt. % to 25 wt. %, 1.0 wt. % to 15.0 wt. %; or 2.0 wt. % to 10.0 wt. % abrasives.

The CMP polishing compositions comprise silicone-containing dispersing agent to disperse the polyurethane beads in aqueous solutions. The silicone-containing dispersing agent also functions as a surface wetting agent dispersing agent.

The silicone-containing dispersing agent includes, but is not limited to, silicone polyethers containing both a water-insoluble silicone backbone and a number of water-soluble polyether pendant groups to provide surface wetting properties. Examples are silicone polyethers containing both a water-insoluble silicone backbone and pendant groups comprising n repeating unit of ethylene oxide (EO) and propylene oxide (PO) (EO-PO) functional groups wherein n is 2 to 25.

Examples of the silicone-containing dispersing agent include Silsurf® E608, Silsurf® J208-6, Silsurf® A208, Silsurf® CR1115, Silsurf® A204, Silsurf® A004-UP, Silsurf® A008-UP, Silsurf® B608, Silsurf® C208, Silsurf® C410, Silsurf® D208, Silsurf® D208, Silsurf® D208-30, Silsurf® Di-1010, Silsurf® Di-1510, Silsurf® Di-15-1, Silsurf® Di-2012, Silsurf® Di-5018-F, Silsurf® G8-I, Silsurf® J1015-O, Silsurf® J1015-O-AC, Silsurf® J208, Silsurf® J208-6, Siltech® OP-8, Siltech® OP-11, Siltech® OP-12, Siltech® OP-15, Siltech® OP-20; the products from Siltech Corporation; 225 Wicksteed Avenue, Toronto Ontario, Canada M4H 1G5.

The concentration range of the silicone-containing dispersing agent is from 0.01 wt. % to 2.0 wt. %, 0.025 wt. % to 1.0 wt. %, or 0.05 wt. % to 0.5 wt. %.

The PIB type of CMP Cu Barrier slurry contains various sized polyurethane beads.

The concentration range of the polyurethane beads is from 0.01 wt. % to 2.0 wt. %, 0.025 wt. % to 1.0 wt. %, or 0.05 wt. % to 0.5 wt. %.

In certain embodiments a weight percentage ratio of abrasive to polyurethane beads is between about 1 to 1 and about 100 to 1, more preferably between about 10 to 1 and about 50 to 1, and most preferably between about 15 to 1 and about 40 to 1.

The surfactants include but are not limited to, anionic surfactants, non-ionic, and cationic surfactants.

The anionic surfactants include but are not limited to organic alkyl sulfonic acids with straight or branched alkyl chains, or their ammonium, sodium, or potassium salts of organic alkyl sulfonate surface wetting agents. Examples are dodecyl sulfonic acid, ammonium salt of dodecyl sulfonate, potassium salt of dodecyl sulfonate, sodium salt, dodecyl sulfonate, 7-Ethyl-2-methyl-4-undecyl sulfate sodium salt (such as Niaproof® 4), or sodium 2-ethylhexyl sulfate (such as Niaproof® 08).

The cationic surfactants include but are not limited to benzyldimethylhexadecylammonium chloride, dodecyltrimethylammonium chloride, dodecyltrimethylammonium hydroxide, cetyltrimethylammonium chloride, and cetyltrimethylammonium hydroxide.

The non-ionic surfactants are the surfactants containing ethylene oxide (EO) and propylene oxide (PO) functional groups include but are not limited to Dynol604, Dynol607, Surfynol 104, Tergitol Min-Form 1X, Tergitol L-62, and Tergitol L-64.

The CMP slurry contains 0.005 wt. % to 0.25 wt. %, 0.001 wt. % to 0.05 wt. %; or 0.002 wt. % to 0.1 wt. % of surfactant.

The chelating agents (or chelators) include, but are not limited to, amino acids, amino acid derivatives, and organic amines.

The amino acids and amino acid derivatives include, but are not limited to, glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane etc.

The organic diamine compounds with two primary amine moieties can be described as the binary chelating agents.

The CMP slurry contains 0.1 wt. % to 18 wt. %; 0.5 wt. % to 15 wt. %; or 2.0 wt. % to 10.0 wt. % of the chelator when it is used in the polishing composition.

The dielectric film removal rate enhancing agents, included but not limited to, potassium silica, sodium silicate, or ammonium silicate.

The CMP slurry contains 0.01 wt. % to 5.0 wt. %; 0.1 wt. % to 3.0 wt. %; or 0.25 wt. % to 2.0 wt. % of the dielectric film removal rate enhancing agent when it is used in the polishing composition.

The corrosion inhibitors can be any known reported corrosion inhibitors.

The corrosion inhibitors for example, include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The CMP slurry contains 0.005 wt. % to 1.0 wt. %; 0.01 wt. % to 0.5 wt. %; or 0.025 wt. % to 0.25 wt. % of corrosion inhibitor.

A biocide having active ingredients for providing more stable shelf time of the Cu Barrier chemical mechanical polishing compositions can be used.

The biocide includes but is not limited to Kathon™, Kathon™ CG/ICP II, from Dow Chemical Co. They have active ingredients of 5-chloro-2-methyl-4-isothiazolin-3-one and/or 2-methyl-4-isothiazolin-3-one.

The CMP slurry contains 0.0001 wt. % to 0.05 wt. %; 0.0001 wt. % to 0.025 wt. %; or 0.0001 wt. % to 0.01 wt. % of biocide when a biocide is optionally used in the polishing composition.

Acidic or basic compounds or pH adjusting agents can be used to allow pH of CMP polishing compositions being adjusted to the optimized pH value,

The pH adjusting agents include, but are not limited to, the following: nitric acid, hydrochloric acid, sulfuric acid, phosphoric acid, other inorganic or organic acids, and mixtures thereof to adjust pH towards acidic direction. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

The CMP slurry contains 0 wt. % to 1 wt. %; 0.01 wt. % to 0.5 wt. %; or 0.1 wt. % to 0.25 wt. % of pH adjusting agent.

The pH of the Cu Barrier polishing compositions is from 3.0 to 12.0; 5.5 to 11.0; or 9.0 to 10.0.

Various per-oxy inorganic or organic oxidizing agents or other types of oxidizing agents can be used to oxidize the metallic copper film to the mixture of copper oxides to allow their quick reactions with chelating agents and corrosion inhibitors.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof. The preferred oxidizer is hydrogen peroxide.

The CMP composition contains 0.1 wt. % to 10 wt. %; 0.25 wt. % to 3 wt. %; or 0.5 wt. % to 2.0 wt. % of oxidizing agents.

The CMP formulations may be shipped in the concentrate form and diluted at the point of use with the addition of water. Component concentrations in a concentrate would be increased as per the dilution factor at point of use. In the illustrated embodiment, the dilution factor is about 2×, preferably between about 1.5× and about 10×, and most preferably between about 2.75× and about 8×.

### EXPERIMENTAL SECTION

### Parameters

Å: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)

SF: polishing composition flow, ml/min
Removal Rates(RR):

| | |
|---|---|
| TEOS RR 1.5 psi | Measured TEOS removal rate at 1.5 psi |
| | down pressure of the CMP tool |
| TEOS RR 2.5 psi | Measured TEOS removal rate at 2.5 psi |
| | down pressure of the CMP tool |
| Cu RR 1.5 psi | Measured Cu removal rate at 1.5 psi |
| | down pressure of the CMP tool |
| Cu RR 2.5 psi | Measured Cu removal rate at 2.5 psi |
| | down pressure of the CMP tool |
| TiN RR 1.5 psi | Measured TiN removal rate at 1.5 psi |
| | down pressure of the CMP tool |
| TiN RR 2.5 psi | Measured TiN removal rate at 2.5 psi |
| | down pressure of the CMP tool |
| BD1 (Low-k) RR 1.5 psi | Measured BD1 removal rate at 1.5 psi |
| | down pressure of the CMP tool |
| BD1(Low-k) RR 2.5 psi | Measured BD1 removal rate at 2.5 psi |
| | down pressure of the CMP tool |

### General Experimental Procedure

All percentages in the compositions are weight percentages unless otherwise indicated.

In the examples presented below, CMP experiments were run using the procedures and experimental conditions given below. The CMP tool that was used in the examples is a 200 mm Mirra® polisher, manufactured by Applied Materials, 3050 Boweres Avenue, Santa Clara, California, 95054. A Fujibo soft pad or other type of soft polishing pad, supplied by Fujibo HOLDINGS, Inc. was used on the platen for the blanket wafer polishing studies. Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton® OX-K colloidal silica, supplied by Planarization Platform of EMD Electronics. at baseline conditions. Polishing experiments were conducted using blanket TEOS wafers. These TEOS blanket wafers were purchased from Silicon Valley Microelectronics, 1150 Campbell Ave, CA, 95126.

Polishing pad, Fujibo H800 soft pad (supplied by Fujibo HOLDINGS, Inc.) or other polyurethane-based polishing pads having a plurality of asperities were used during Cu Barrier CMP.

### WORKING EXAMPLE

### Example 1

The reference CMP composition (Non-PIB Cu Barrier Sample) comprised of 0.0196 wt. % benzotriazole, 0.01018 wt. % Dynol607, 1.0553 wt. % potassium silicate, 0.1916 wt. % nitric acid, 0.050 wt. % Silsurf E608, and 5.1730 wt. % high purity colloidal silica particles abrasive.

The testing PIB CMP Cu Barrier composition (PIB Cu Barrier w PU Beads) was prepared by adding 0.25 wt. % 35 μm sized polyurethane beads (PU beads) into the reference Cu Barrier CMP composition.

In the illustrated embodiment of the PIB Cu Barrier slurry with PU beads, a weight percentage ratio of abrasive (5.1730 wt. %) to polyurethane beads (0.25 wt. %) is 20.69 to 1 (about 20 to 1).

1.0 wt. % H₂O₂ was added into the CMP compositions at the point of use.

Both compositions had a pH around 9.72.

The TEOS removal rates were tested using those two compositions through 3 hour marathon polishing testing, and the averaged TEOS removal rate results at 1.5 psi DF and 2.5 psi DF were listed in Table 1 and 2.

TABLE 1
Ave. TEOS Removal Rate Comparison at 1.5 psi DF

| Compositions | Ave. TEOS RR (Å/min.) |
|---|---|
| Non-PIB Cu Barrier Sample | 733 |
| PIB Cu Barrier w PU Beads | 698 |

TABLE 2
Ave. TEOS Removal Rate Comparison at 2.5 psi DF

| Compositions | Ave. TEOS RR (Å/min.) |
|---|---|
| Non-PIB Cu Barrier Sample | 1234 |
| PIB Cu Barrier w PU Beads | 1204 |

As the results shown in Table 1, and Table 2, both compositions gave stable and very similar TEOS removal rates over 3 hour marathon polishing testing under the same fractional conditioning conditions.

The polishing pad cutting rates are the important parameters to judge the polishing pad lifetime. To increase the polishing pad lifetime is very important in Cu Barrier P3 CMP processes.

TABLE 3
Fujibo Soft Pad Cutting Rate Comparison

| | Ave. | Disk | Pad |
|---|---|---|---|
| | TEOS RR | Conditioning | Cutting Rate |
| Compositions | (Å/min.) | time (%) | (micron/per hr.) |
| Non-PIB Cu | 1175 | 100% | 39 +/− 3 |
| Barrier Sample | | | |
| Non-PIB Cu | 1234 | 16% | 19 +/− 3 |
| Barrier Sample | | | |
| PIB Cu Barrier | 1204 | 16% | 11 +/− 3 |
| w PU Beads | | | |

The Fujibo soft pad cutting rates were measured and compared in the disclosure herein on using Non-PIB Cu barrier samples under full disk conditioning condition (100%), or under fractional conditioning condition (16% of full disk conditioning time) vs the pad cutting rates using PIB Cu barrier sample under fractional conditioning condition (16% of full disk conditioning time) through 3 hour marathon polishing testing to polis TEOS wafers. The pad cutting comparison results were listed in Table 3.

The results in Table 3 have shown one of the key benefits of using micron sized PU beads in PIB-type Cu Barrier CMP compositions. While still maintaining the stable and desirable oxide removal rates, PIB-type Cu barrier composition provided about 4× increased soft pad lifetime under 16% fractional conditioning than the Non-PIB type Cu barrier composition under 100% conditioning condition.

The results in Table 3 also have shown that: while still maintaining the stable and desirable oxide removal rates, PIB-type Cu barrier composition provided about 2× increased soft pad lifetime under 16% fractional conditioning than the Non-PIB type Cu barrier s composition under the same 16% conditioning condition.

The above listed pad life increase results provide the good benefits for semiconductor electronic device fabrication processes in terms of not only reducing the consumption of polishing pads and conditioning disks and production costs but also providing the improved protection to the environments.

The embodiments of this disclosure listed above, including the working example, are exemplary of numerous embodiments that may be made of this disclosure. It is contemplated that numerous other configurations of the process may be used, and the materials used in the process may be elected from numerous materials other than those specifically disclosed.

1. A chemical mechanical polishing (CMP) composition comprising:
an abrasive,
polyurethane (PU) beads ranging from 2 to 100 μm, 10 to 80 μm, 20 to 70 μm, or 30 to 50 μm;
a silicone-containing dispersing agent;
a corrosion inhibitor,
a liquid carrier such as water;
and optionally,
a surfactant to enhance film surface wetting;
an additive to boost dielectric film removal rates
a chelating agent,
a biocide;
pH adjuster;
an oxidizer added at the point of use; and
the pH of the composition is from 8.0 to 12.0; 8.5 to 11.0; or 9.0 to 10.0;
wherein a weight percentage ratio of abrasive to polyurethane beads is between about 1 to 1 and about 100 to 1, more preferably between about 10 to 1 and about 50 to 1, and most preferably between about 15 to 1 and about 40 to 1.

2. The CMP composition of claim 1, wherein the abrasive are abrasive particles selected from the group consisting of colloidal silica; colloidal silica particles doped by other metal oxide within lattice of the colloidal silica; colloidal aluminum oxide selected from the group consisting of alpha-, beta-, and gamma-types of aluminum oxides; colloidal and photoactive titanium dioxide; cerium oxide; colloidal cerium oxide; inorganic metal oxide particles selected from the group consisting of alumina, titania, zirconia, ceria; and diamond particles; silicon nitride particles; mono-modal, bi-modal, or multi-modal colloidal abrasive particles; organic polymer-based soft abrasive particles; surface-coated or modified abrasive particles; and combinations thereof; and the abrasive ranges from 0.10 wt. % to 25 wt. %; 1.0 wt. % to 15 wt. %; or 2.0 wt. % to 10.0 wt. %.

3. The CMP composition of claim 1, wherein the polyurethane (PU) beads have a size from 2 to 100 μm, 10 to 80 μm, 20 to 70 μm, or 30 to 50 μm; and ranges from 0.01 wt. % to 2.0 wt. %, 0.025 wt. % to 1.0 wt. %, or 0.05 wt. % to 0.5 wt. %.

4. The CMP composition of claim 1, wherein the silicone-containing dispersing agent comprises a silicone polyether containing both a water-insoluble silicone backbone and water-soluble polyether pendant groups, and the silicone-containing dispersing agent ranges from 0.01 wt. % to 2.0 wt. %, 0.025 wt. % to 1.0 wt. %, or 0.05 wt. % to 0.5 wt. %.

5. The CMP composition of claim 1, wherein the silicone-containing dispersing agent comprises a silicone polyether containing both a water-insoluble silicone backbone and pendant groups comprising n repeating unit of ethylene oxide (EO) and propylene oxide (PO) (EO-PO) functional groups wherein n is 2 to 25.

6. The CMP composition of claim 1, wherein the CMP composition comprises the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof; and the corrosion inhibitor ranges from 0.005 wt. % to 1.0 wt. %; 0.01 wt. % to 0.5 wt. %; or 0.025 wt. % to 0.25 wt. %.

7. The CMP composition of claim 1, wherein the CMP composition comprises the surfactant selected from the group consisting of anionic, non-ionic containing ethylene oxide (EO) and propylene oxide (PO) functional groups, and cationic surfactant; and the surfactant ranges from 0.005 wt. % to 0.25 wt. %, 0.001 wt. % to 0.05 wt. %; or 0.002 wt. % to 0.1 wt. %.

8. The CMP composition of claim 1, wherein the CMP composition comprises the additive to boost dielectric film removal rate selected from the group consisting of potassium silicate, sodium silicate, ammonium silicate, and combinations thereof; and the additive to boost dielectric film removal rate ranges from 0.01 wt. % to 5.0 wt. %; 0.1 wt. % to 3.0 wt. %; or 0.25 wt. % to 2.0 wt. %.

9. The CMP composition of claim 1, wherein the CMP composition comprises the chelating agent selected from the group consisting of glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and the chelating agent ranges from 0.1 wt. % to 18 wt. %; 0.5 wt. % to 15 wt. %; 1.0 wt. % to 10.0 wt. %; or 2.0 wt. % to 10.0 wt. %.

10. The CMP composition of claim 1, wherein the CMP composition wherein the chelating agent is selected from the group consisting of the group consisting of glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof; and
wherein the corrosion inhibitor is selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof.

11. The CMP composition of claim 1, wherein the CMP composition comprises the biocide having an active ingredient selected from the group consisting of 5-chloro-2-methyl-4-isothiazolin-3-one, 2-methyl-4-isothiazolin-3-one, and combinations thereof; and the biocide ranges from 0.0001 wt. % to 0.05 wt. %; 0.0001 wt. % to 0.025 wt. %; or 0.0001 wt. % to 0.01 wt. %.

12. The CMP composition of claim 1, wherein the CMP composition comprises the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and the oxidizing agent ranges from 0.1 wt. % to 10 wt. %; 0.25 wt. % to 3 wt. %; or 0.5 wt. % to 2.0 wt. %.

13. The CMP composition of claim 1, wherein the chelating agent is selected from the group consisting of the group consisting of glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, 2,2-dimethyl-1,3-propanediamine and 2,2-dimethyl-1,4-butanediamine, ethylenediamine, 1,3-diaminepropane, 1,4-diaminebutane, and combinations thereof;
the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and
the corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof.

14. The CMP composition of claim 1, wherein the pH adjusting agent is selected from the group consisting of nitric acid, hydrochloric acid, sulfuric acid, phosphoric acid, other inorganic or organic acids, and mixtures thereof to adjust pH towards acidic direction; or is selected from the group consisting of sodium hydride, potassium hydroxide, ammonium hydroxide, tetraalkyl ammonium hydroxide, organic amines, and combinations thereof to adjust pH towards alkaline direction.

15. The CMP composition of claim 1, wherein the CMP composition comprises colloidal silica particles, silicone-containing dispersing agent comprising a silicone polyether containing both a water-insoluble silicone backbone and pendant groups comprising n repeating unit of ethylene oxide (EO) and propylene oxide (PO) (EO-PO) functional groups wherein n is 2 to 25, corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof; and polyurethane (PU) beads.

16. The CMP composition of claim 1, wherein the CMP composition comprises colloidal silica particles, silicone-containing dispersing agent comprising a silicone polyether containing both a water-insoluble silicone backbone and pendant groups comprising n repeating unit of ethylene oxide (EO) and propylene oxide (PO) (EO-PO) functional groups wherein n is 2 to 25, corrosion inhibitor selected from the group consisting of 1,2,4-triazole, 3-amino-1,2,4-triazole, benzotriazole and benzotriazole derivatives, tetrazole and tetrazole derivatives, imidazole and imidazole derivatives, benzimidazole and benzimidazole derivatives, pyrazole and pyrazole derivatives, tetrazole and tetrazole derivatives, and combinations thereof; surfactant selected from the group consisting of anionic surfactant, non-ionic surfactant containing ethylene oxide (EO) and propylene oxide (PO) functional groups, and cationic surfactant; an additive to boost dielectric film removal rate selected from the group consisting of potassium silica, sodium silicate, ammonium silicate, and combinations thereof; the oxidizing agent selected from the group consisting of periodic acid, hydrogen peroxide, potassium iodate, potassium permanganate, ammonium persulfate, ammonium molybdate, ferric nitrate, nitric acid, potassium nitrate, and combinations thereof; and polyurethane (PU) beads.

17. A method of chemical mechanical polishing a semiconductor substrate, comprising steps of:
providing the semiconductor substrate having a surface containing at least one material selected from the group consisting of Cu, TEOS, low-k (LK) or ultra low-k (Ultra-LK), TiN, Ti, Ta, and TaN;
providing a polishing pad, the polishing pad comprising polyurethane and having a plurality of asperities;
providing the chemical mechanical polishing (CMP) formulation of claim 1;
contacting the surface containing at least one of material selected from the group consisting of Cu, TEOS, low-k (LK) or ultra low-k (Ultra-LK), TiN, Ti, Ta, and TaN with the polishing pad and the chemical mechanical polishing formulation; and
polishing the surface containing at least one material selected from the group consisting of Cu, TEOS, low-k (LK) or ultra low-k (Ultra-LK), TiN, Ti, Ta, and TaN;
wherein at least a portion of the surface containing at least one material selected from the group consisting of Cu, TEOS, low-k (LK) or ultra low-k (Ultra-LK), TiN, Ti, Ta, and TaN is in contact with both the polishing pad and the chemical mechanical polishing formulation.

18. The method of claim 17, further comprising, conditioning the polishing pad with a diamond cutting disk.

19. A system of chemical mechanical polishing, comprising
a semiconductor substrate having a surface containing at least one material selected from the group consisting of Cu, TEOS, low-k (LK) or ultra low-k (Ultra-LK), TiN, Ti, Ta, and TaN;
a polishing pad, the polishing pad comprising polyurethane and having a plurality of asperities; and
the chemical mechanical polishing (CMP) formulation of claim 1;
wherein at least a portion of the surface containing at least one material selected from the group consisting of Cu, TEOS, low-k (LK) or ultra low-k (Ultra-LK), TiN, Ti, Ta, and TaN is in contact with both the polishing pad and the chemical mechanical polishing formulation.
